(19) United States
(12) Patent Application Publication
(10) Pub. No.: US 2016/0005677 A1
(43) Pub. Date: Jan. 7, 2016

(54) THERMALLY CONDUCTIVE SHEET, CURED PRODUCT THEREOF, AND SEMICONDUCTOR DEVICE

(71) Applicant: SUMITOMO BAKELITE CO., LTD., Tokyo (JP)

(72) Inventors: Shunsuke Mochizuki, Tokyo (JP); Kazuya Kitagawa, Tokyo (JP); Yoji Shirato, Tokyo (JP); Keita Nagahashi, Tokyo (JP); Mika Tsuda, Tokyo (JP); Kazuya Hirasawa, Kariya-shi (JP); Motomi Kurokawa, Aichi-ken (JP)

(73) Assignee: SUMITOMO BAKELITE CO., LTD., Tokyo (JP)

(21) Appl. No.: 14/789,207

(22) Filed: Jul. 1, 2015

(30) Foreign Application Priority Data
Jul. 2, 2014 (JP) 2014-137236

(51) Int. Cl. H01L 23/373; H01L 23/495; C09K 5/14

(52) U.S. Cl. CPC H01L 23/3737; C09K 5/14; H01L 23/49568

(57) ABSTRACT

A thermally conductive sheet includes a thermosetting resin and an inorganic filler material. When a pore diameter distribution is measured through mercury intrusion technique for the inorganic filler material, a pore diameter distribution curve of the inorganic filler material has a first maximum value in the range where the pore diameter R is greater than or equal to 0.1 μm and less than or equal to 5.0 μm, and a second maximum value in the range where the pore diameter R is greater than or equal to 10 μm and less than or equal to 30 μm, and the difference between a second pore diameter at the second maximum value and a first pore diameter at the first maximum value is greater than or equal to 9.9 μm and less than or equal to 25 μm.

This application is based on Japanese patent application No. 2014-137236, the content of which is incorporated hereinto by reference.

### BACKGROUND

1. Technical Field

The present invention relates to a thermally conductive sheet, a cured product of the thermally conductive sheet, and a semiconductor device.

2. Related Art

It is known in the related art that an inverter device or a power semiconductor device is configured by mounting electronic components including a semiconductor chip such as an insulated gate bipolar transistor (IGBT) or a diode, a resistor, a capacitor, and the like on a substrate.

These power control devices are applied to various devices depending on the breakdown voltage and the current capacity of the power control devices. Particularly, use of these power control devices is becoming widespread in various electrical machines in terms of recent environmental problems and promotion of saving energy.

It is particularly desired for an on-board power control device to be reduced in size, to occupy a lesser space, and to be installed in an engine room. Inside the engine room is a harsh environment in which, for example, the temperature is high and is greatly changed, and thus a member that has more excellent thermal radiation properties and insulating properties at a high temperature is required in the engine room.

In Japanese Unexamined Patent Publication No. 2011-216619, for example, disclosed is a semiconductor device in which a semiconductor chip is mounted on a supportive body such as a lead frame, and the supportive body and a thermal radiator panel are bonded together by an insulating resin layer.

Such a semiconductor device, however, does not have sufficiently satisfactory thermal radiation properties and insulating properties at a high temperature. Thus, it may be difficult to sufficiently radiate heat of the semiconductor chip outside or to secure insulating properties of the electronic components, in which case the performance of the semiconductor device decreases.

### SUMMARY

In one embodiment, there is provided a thermally conductive sheet that includes a thermosetting resin and an inorganic filler material which is dispersed in the thermosetting resin,

in which when a pore diameter distribution is measured through mercury intrusion technique for the inorganic filler material that is included in an incineration residue after a cured product of the thermally conductive sheet is heated at 700° C. for four hours and is incinerated,

a pore diameter distribution curve of the inorganic filler material, that is measured through the mercury intrusion technique and is plotted with a pore diameter R as a horizontal axis and a logarithmic derivative of a pore volume (dV/d log R) as a vertical axis, has

a first maximum value in the range where the pore diameter R is greater than or equal to 0.1 μm and less than or equal to 5.0 μm, and

a second maximum value in the range where the pore diameter R is greater than or equal to 10 μm and less than or equal to 30 μm, and

the difference between a second pore diameter at the second maximum value and a first pore diameter at the first maximum value is greater than or equal to 9.9 μm and less than or equal to 25 μm.

Strength of the inorganic filler material can be improved when the pore distribution curve of the inorganic filler material in the thermally conductive sheet has the first maximum value in the range where the pore diameter R is greater than or equal to 0.1 μm and less than or equal to 5.0 μm and the second maximum value in the range where the pore diameter R is greater than or equal to 10 μm and less than or equal to 30 μm, and the difference between the second pore diameter at the second maximum value and the first pore diameter at the first maximum value is greater than or equal to 9.9 μm. In consequence, the shape and orientation of the inorganic filler material can be held to a certain extent before and after manufacturing of the thermally conductive sheet. Accordingly, thermal conductivity of the thermally conductive sheet and the cured product thereof can be improved, and thus thermal radiation properties of a semiconductor device obtained can be improved.

In addition, when the difference between the second pore diameter and the first pore diameter is less than or equal to 25 μm, the thermosetting resin sufficiently moves into the inorganic filler material, and thus voids occur to a lesser extent in the thermally conductive sheet. Accordingly, insulating properties of the thermally conductive sheet and the cured product thereof can be improved, and thus the insulating reliability of a semiconductor device obtained is improved.

Furthermore, when the difference between the second pore diameter and the first pore diameter is less than or equal to 25 μm, the filling ability of the inorganic filler material in the thermally conductive sheet is high, and the area of contact between the inorganic filler materials is large. Accordingly, thermal conductivity of the thermally conductive sheet and the cured product thereof can be improved.

What is inferred from above is that it is possible to obtain a thermally conductive sheet and a cured product thereof having an excellent balance of thermal radiation properties and insulating properties according to the present embodiment in which the difference between the second pore diameter and the first pore diameter of the inorganic filler material in the thermally conductive sheet is controlled to be in the above range. In addition, a highly durable semiconductor device can be realized by applying the thermally conductive sheet to a semiconductor device.

In another embodiment, there is provided a cured product of a thermally conductive sheet that is obtained by curing the thermally conductive sheet.

In still another embodiment, there is provided a semiconductor device including:

a metal plate;

a semiconductor chip that is disposed on a first face side of the metal plate;

a thermally conductive material that is bonded to a second face of the metal plate opposite from the first face; and

an encapsulating resin that encapsulates the semiconductor chip and the metal plate,

in which the thermally conductive material is formed by the thermally conductive sheet.

According to the present invention, it is possible to provide a thermally conductive sheet, a cured product thereof having an excellent balance of thermal radiation properties and insulating properties, and a highly durable semiconductor device.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view of a semiconductor device according to one embodiment of the present invention.

FIG. 2 is a sectional view of the semiconductor device according to one embodiment of the present invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, an embodiment of the present invention will be described with reference to the drawings. The same element is designated by the same reference numeral throughout the drawings, and a detailed description thereof will not be repeated. The drawings are for schematic purposes only and do not necessarily have the same dimensions and proportions as real-world dimensions and proportions. In addition, “to” between two numbers represents a range of greater than or equal to one number and less than or equal to the other.

First, a thermally conductive sheet according to the present embodiment will be described.

The thermally conductive sheet according to the present embodiment includes a thermosetting resin (A) and an inorganic filler material (B) dispersed in the thermosetting resin (A).

A cured product of the thermally conductive sheet is heated at 700° C. for four hours to be incinerated, and pore diameter distribution is measured in the inorganic filler material (B) included in an incineration residue through mercury intrusion technique. At this time, a pore diameter distribution curve of the inorganic filler material (B), plotted with a pore diameter R measured through the mercury intrusion technique on the horizontal axis and a logarithmic derivative of a pore volume (dV/d log R) on the vertical axis, has a first maximum value in the range where the pore diameter R is greater than or equal to 0.1 μm and less than or equal to 5.0 μm, preferably greater than or equal to 0.2 μm and less than or equal to 1.5 μm, and more preferably greater than or equal to 0.2 μm and less than or equal to 1.0 μm. The pore diameter distribution curve has a second maximum value in the range where the pore diameter R is greater than or equal to 10 μm and less than or equal to 30 μm, preferably greater than or equal to 11 μm and less than or equal to 25 μm, and more preferably greater than or equal to 12 μm and less than or equal to 20 μm. The difference between a second pore diameter at the second maximum value and a first pore diameter at the first maximum value is greater than or equal to 9.9 μm and less than or equal to 25 μm, preferably greater than or equal to 11 μm and less than or equal to 23 μm, and more preferably greater than or equal to 12 μm and less than or equal to 20 μm.

When two or more maximum values are in each of the above ranges, the largest one is the first maximum value or the second maximum value.

The pore diameter R of the inorganic filler material (B) can be measured by, for example, a porosimeter used in mercury intrusion technique. When the pore distribution curve of the inorganic filler material (B) has two or more peaks in the range where the pore diameter is greater than or equal to 0.03 μm and less than or equal to 100 μm, normally the peak in the range where the pore diameter is greater than or equal to 0.03 μm and less than or equal to 3.0 μm indicates the volume of voids in particles, and the peak in the range where the pore diameter is greater than or equal to 3.0 μm and less than or equal to 100 μm indicates the volume of voids between particles. Thus, the first pore diameter indicates a pore diameter in particles, and the second pore diameter indicates a pore diameter between particles. The pore diameter R having the peak in the above range means the maximum value of the peak is in the above range. The pore diameter indicates the diameter of a pore in the present embodiment. The first pore diameter and the second pore diameter are mode diameters.

According to the present embodiment, the strength (cohesive force in the case of secondary agglomerated particles) of the inorganic filler material (B) can be improved when the difference between the second pore diameter and the first pore diameter is greater than or equal to the lower limit value, and in consequence, the shape and the orientation (orientation of primary particles in the case of secondary agglomerated particles) of the inorganic filler material (B) can be held to a certain extent before and after manufacturing of the thermally conductive sheet. Accordingly, thermal conductivity of the thermally conductive sheet and the cured product thereof can be improved, and thus thermal radiation properties of a semiconductor device obtained can be improved. Particularly, when the inorganic filler material (B) is secondary agglomerated particles, the contact between primary particles and the random orientation of primary particles are held by maintaining the shape of the secondary agglomerated particles to a certain extent. Thus, thermal conductivity of the thermally conductive sheet and the cured product thereof can be further improved.

In addition, when the difference between the second pore diameter and the first pore diameter is less than or equal to the upper limit value, the thermosetting resin (A) sufficiently moves into the inorganic filler material (B), and thus voids occur to a lesser extent in the thermally conductive sheet. Accordingly, insulating properties of the thermally conductive sheet and the cured product thereof can be improved, and thus the insulating reliability of a semiconductor device obtained is improved.

Furthermore, when the difference between the second pore diameter and the first pore diameter is less than or equal to the upper limit value, the filling ability of the inorganic filler material (B) in the thermally conductive sheet is high, and the area of contact between the inorganic filler materials (B) is large. Accordingly, thermal conductivity of the thermally conductive sheet and the cured product thereof can be improved.

What is inferred from the description thus far is that it is possible to obtain a thermally conductive sheet and a cured product thereof having excellent thermal conductivity and thermal radiation properties according to the present embodiment in which the difference between the second pore diameter and the first pore diameter of the inorganic filler material (B) in the thermally conductive sheet is controlled to be in the above range. In addition, a highly durable semiconductor device can be realized by applying the thermally conductive sheet to a semiconductor device.

In the present embodiment, the thermally conductive sheet is in a B-stage. The thermally conductive sheet after being cured is called a “cured product of the thermally conductive sheet”. The thermally conductive sheet after being applied to a semiconductor device and being cured is called a “thermally conductive material”. The cured product of the thermally conductive sheet includes the thermally conductive material. In addition, in the present embodiment, the cured product of the thermally conductive sheet is in a C-stage and is obtained by heating the thermally conductive sheet in a B-stage, for example, at 180° C. under 10 MPa for 40 minutes and curing thereafter.

The thermally conductive sheet, for example, is disposed at a bonded interface in a semiconductor device where high thermal conductivity is required and enhances thermal conductivity from a heating element to a radiator. Accordingly, failure due to varying of characteristics of a semiconductor chip and the like is suppressed, and the stability of a semiconductor device is improved.

An example of a semiconductor device to which the thermally conductive sheet according to the present embodiment is applied is a semiconductor device having a structure in which a semiconductor chip is disposed on a heat sink (metal plate), and the thermally conductive material is disposed on the face of the heat sink opposite from the face to which the semiconductor chip is bonded.

Another example of a semiconductor package to which the thermally conductive sheet according to the present embodiment is applied is a semiconductor package that is provided with the thermally conductive material, a semiconductor chip bonded to one face of the thermally conductive material, a metal member bonded to the face of the thermally conductive material opposite from the one face, and an encapsulating resin encapsulating the thermally conductive material, the semiconductor chip, and the metal member.

A highly durable semiconductor device can be realized by using the thermally conductive sheet according to the present embodiment. The reason may not necessarily be apparent but is considered as follows.

According to a review by the inventors, it is apparent that a semiconductor device in which a thermally conductive sheet in the related art is used experiences a decrease or the like in the thermal conductivity or insulating properties of the thermally conductive sheet when being placed for long hours in an environment such as in the engine room of an automobile where the temperature changes rapidly, and the durability of the semiconductor device decreases. Thus, the semiconductor device in the related art is of inferior durability.

Meanwhile, a semiconductor device in which the thermally conductive sheet according to the present embodiment is used is of excellent durability even in an environment in which the temperature changes rapidly. The reason considered for this is that the thermally conductive sheet according to the present embodiment has a structure in which voids hardly occur, the inorganic filler material (B) in the thermally conductive sheet maintains the shape thereof prior to manufacturing of the thermally conductive sheet to a certain extent, the filling ability of the inorganic filler material (B) in the thermally conductive sheet is high, and the area of contact between the inorganic filler materials (B) is large.

Insulating properties of the thermally conductive sheet and the cured product thereof can be improved because voids occur to a lesser extent in the thermally conductive sheet, and thermal conductivity of the thermally conductive sheet and the cured product thereof can be improved by holding the shape and orientation of the inorganic filler material (B) to a certain extent before and after manufacturing of the thermally conductive sheet and by increasing the area of contact between the inorganic filler materials (B).

From the above reason, the thermally conductive sheet and the cured product thereof according to the present embodiment have a well-balanced structure in terms of thermal conductivity and insulating properties. Thus, it is inferred that a semiconductor device having excellent durability is obtained by using the thermally conductive sheet according to the present embodiment.

In the thermally conductive sheet according to the present embodiment, a cumulative pore volume V1 in the range where the pore diameter R is greater than 5.0 μm and less than or equal to 180 μm is preferably greater than or equal to 0.4 mL/g and less than or equal to 1.0 mL/g and more preferably greater than or equal to 0.5 mL/g and less than or equal to 0.9 mL/g. A cumulative pore volume V2 in the range where the pore diameter R is greater than or equal to 0.01 μm and less than or equal to 180 μm is preferably greater than or equal to 0.8 mL/g and less than or equal to 1.7 mL/g and more preferably greater than or equal to 0.9 mL/g and less than or equal to 1.6 mL/g.

The cumulative pore volume V1 indicates the volume of pores between particles, and the difference (V2−V1) indicates the volume of pores in particles.

When the cumulative pore volume V1 and the cumulative pore volume V2 are in the above range, it is possible to obtain the thermally conductive sheet and the cured product thereof having a more excellent balance of thermal radiation properties and insulating properties.

The first pore diameter and the second pore diameter of the inorganic filler material (B) according to the present embodiment may be controlled by appropriately adjusting types and mixing proportions of each component constituting the thermally conductive sheet and adjusting a method for manufacturing the thermally conductive sheet.

Examples of factors in controlling the first pore diameter and the second pore diameter of the present embodiment particularly include appropriate selection of the type of the thermosetting resin (A), appropriate selection of a solvent constituting a resin varnish for forming the thermally conductive sheet, inclusion of applying compressive pressure to the thermally conductive sheet, aging the resin varnish to which the thermosetting resin (A) and the inorganic filler material (B) are added, conditions for applying heat and pressure through the aging, and conditions for baking the inorganic filler material (B).

The cured product of the thermally conductive sheet according to the present embodiment has a glass transition temperature preferably greater than or equal to 175° C. and more preferably greater than or equal to 190° C., which is measured through dynamic viscoelasticity measurement under conditions of a rate of temperature increase of 5° C./min and a frequency of 1 Hz. The upper limit value of the glass transition temperature is not particularly limited but is, for example, less than or equal to 300° C.

The glass transition temperature of the cured product of the thermally conductive sheet can be measured as follows. First, the cured product of the thermally conductive sheet is obtained by heating the thermally conductive sheet at 180° C. under 10 MPa for 40 minutes. Next, a glass transition temperature (Tg) of the cured product obtained is measured through DMA (dynamic viscoelasticity measurement) under conditions of a rate of temperature increase of 5° C./min and a frequency of 1 Hz.

When the glass transition temperature is greater than or equal to the lower limit value, release of movement of conductive components can be further suppressed, and thus a decrease in insulating properties of the thermally conductive sheet due to temperature increase can be further suppressed. In consequence, it is possible to realize a semiconductor device having more excellent insulating reliability.

The glass transition temperature can be controlled by appropriately adjusting types and mixing proportions of each component constituting the thermally conductive sheet and adjusting a method for manufacturing the thermally conductive sheet.

The thermally conductive sheet according to the present embodiment, for example, is disposed between a heating element such as a semiconductor chip and a substrate such as a lead frame or an interconnect substrate (interposer) on which the heating element is mounted or between the substrate and a thermal radiation member such as a heat sink. Accordingly, heat generated from the heating element can be effectively radiated outside a semiconductor device. Thus, durability of a semiconductor device can be improved.

The plan shape of the thermally conductive sheet according to the present embodiment is not particularly limited and is able to be appropriately selected in accordance with the shape of the thermal radiation member, the heating element, and the like. For example, the plan shape of the thermally conductive sheet can be rectangular. The film thickness of the cured product of the thermally conductive sheet is preferably greater than or equal to 50 μm and less than or equal to 250 μm. Accordingly, it is possible to transfer heat from the heating element more effectively to the thermal radiation member while improving mechanical strength and thermal resistance. Furthermore, the thermally conductive material has a more excellent balance of thermal radiation properties and insulating properties.

The thermally conductive sheet according to the present embodiment includes a thermosetting resin (A) and an inorganic filler material (B) dispersed in the thermosetting resin (A). Hereinafter, each material constituting the thermally conductive sheet according to the present embodiment will be described.

### (Thermosetting Resin (A))

Examples of the thermosetting resin (A) include an epoxy resin, a cyanate resin, a polyimide resin, a benzoxazine resin, an unsaturated polyester resin, a phenol resin, a melamine resin, a silicone resin, a bismaleimide resin, and an acrylic resin. One of the examples may be used alone as the thermosetting resin (A), or two or more thereof may be used together.

Examples of the epoxy resin include a bisphenol epoxy resin such as a bisphenol A epoxy resin, a bisphenol F epoxy resin, a bisphenol E epoxy resin, a bisphenol S epoxy resin, a bisphenol M epoxy resin (4,4′-(1,3-phenylenediisopropylidene)bisphenol epoxy resin), a bisphenol P epoxy resin (4,4′-(1,4-phenylenediisopropylidene)bisphenol epoxy resin), or a bisphenol Z epoxy resin (4,4′-cyclohexylidenebisphenol epoxy resin); a novolac epoxy resin such as a phenol novolac epoxy resin, a cresol novolac epoxy resin, a tetraphenol ethane novolac epoxy resin, or a novolac epoxy resin having the structure of a condensed aromatic hydrocarbon; an epoxy resin having a biphenyl skeleton; an arylalkylene epoxy resin such as a xylene epoxy resin or an epoxy resin having a biphenyl aralkyl skeleton; a naphthalene epoxy resin such as a naphthylene ether epoxy resin, a naphthol epoxy resin, a naphthalenediol epoxy resin, bifunctional to quadfunctional epoxy naphthalene resins, a binaphthyl epoxy resin, or an epoxy resin having a naphthalene aralkyl skeleton; an anthracene epoxy resin; a phenoxy epoxy resin; an epoxy resin having a dicyclopentadiene skeleton; a norbornene epoxy resin; an epoxy resin having an adamantane skeleton; a fluorene epoxy resin; and an epoxy resin having a phenol aralkyl skeleton.

It is preferable that, among these examples, an epoxy resin having a dicyclopentadiene skeleton, an epoxy resin having a biphenyl skeleton, an epoxy resin having an adamantane skeleton, an epoxy resin having a phenol aralkyl skeleton, an epoxy resin having a biphenyl aralkyl skeleton, an epoxy resin having a naphthalene aralkyl skeleton, a cyanate resin, or the like is used as the thermosetting resin (A).

Using such a thermosetting resin (A) allows the cured product of the thermally conductive sheet according to the present embodiment to have a high glass transition temperature and allows thermal radiation properties and insulating properties of the thermally conductive sheet and the cured product thereof to be improved.

The content of the thermosetting resin (A) in the thermally conductive sheet according to the present embodiment is preferably greater than or equal to 1 mass % and less than or equal to 30 mass % and more preferably greater than or equal to 5 mass % and less than or equal to 28 mass % with respect to the thermally conductive sheet as 100 mass %. When the content of the thermosetting resin (A) is greater than or equal to the lower limit value, handleability is improved, and forming the thermally conductive sheet is facilitated. When the content of the thermosetting resin (A) is less than or equal to the upper limit value, strength and incombustibility of the thermally conductive sheet and the cured product thereof are further improved, and thermal conductivity of the thermally conductive sheet and the cured product thereof is further improved.

### (Inorganic Filler Material (B))

Examples of the inorganic filler material (B) include silica, alumina, boron nitride, aluminum nitride, silicon nitride, and silicon carbide. One of these may be used alone, or two or more may be used together.

The shape of the inorganic filler material (B) is not particularly limited and is normally spherical.

The inorganic filler material (B) is preferably secondary agglomerated particles that are formed by agglomerating primary particles of scaly boron nitride in terms of further improving thermal conductivity of the thermally conductive sheet and the cured product thereof according to the present embodiment.

Secondary agglomerated particles that are formed by agglomerating primary particles of scaly boron nitride can be formed by, for example, mixing a binder into scaly boron nitride to prepare a slurry, agglomerating the slurry through spray drying or the like, and baking the slurry. The baking temperature is, for example, 1200 to 2500° C. The baking time is, for example, 2 to 24 hours.

Normally, as the baking temperature or the baking time is increased, the first pore diameter can be increased, and the second pore diameter can be decreased. In consequence, the difference between the second pore diameter and the first pore diameter can be decreased.

As such, when secondary agglomerated particles obtained by incinerating primary particles of scaly boron nitride are used as the inorganic filler material (B), an epoxy resin having a dicyclopentadiene skeleton is preferably used as the thermosetting resin (A) in terms of improving dispersibility of the inorganic filler material (B) in the thermosetting resin (A).

The average particle diameter of the inorganic filler material (B) is, for example, preferably greater than or equal to 5 μm and less than or equal to 180 μm and more preferably greater than or equal to 10 μm and less than or equal to 100 μm. Accordingly, it is possible to realize the thermally conductive sheet and the cured product thereof having a more excellent balance of thermal conductivity and insulating properties.

The average particle diameter of the inorganic filler material (B) is the median diameter (D₅₀) of a particle size distribution when a particle size distribution of particles is measured by a laser diffraction particle size distribution measuring device on a volume basis.

The average major diameter of primary particles of scaly boron nitride constituting the secondary agglomerated particles is preferably greater than or equal to 0.01 μm and less than or equal to 20 μm and more preferably greater than or equal to 0.1 μm and less than or equal to 15 μm.

Accordingly, it is possible to realize the thermally conductive sheet and the cured product thereof having a more excellent balance of thermal conductivity and insulating properties.

The average major diameter can be measured by using an electron micrograph. For example, the average major diameter is measured in the following procedure. First, the secondary agglomerated particles are cut by a microtome or the like to prepare a sample. Next, a section of the secondary agglomerated particles magnified by a few thousand times is captured several times by a scanning electron microscope. Next, an arbitrary one of the secondary agglomerated particles is selected, and the major diameter of a primary particle of the scaly boron nitride is measured from the pictures. At this time, the major diameter is measured for 10 or more primary particles, and the average value of the major diameters is used as the average major diameter.

The content of the inorganic filler material (B) in the thermally conductive sheet according to the present embodiment is preferably greater than or equal to 50 mass % and less than or equal to 95 mass %, more preferably greater than or equal to 55 mass % and less than or equal to 88 mass %, and particularly preferably greater than or equal to 60 mass % and less than or equal to 80 mass % with respect to the thermally conductive sheet as 100 mass %.

By setting the content of the inorganic filler material (B) to be greater than or equal to the lower limit value, thermal conductivity and mechanical strength of the thermally conductive sheet and the cured product thereof can be improved more effectively. Meanwhile, by setting the content of the inorganic filler material (B) to be less than or equal to the upper limit value, deposition and workability of a resin composition are improved, and uniformity of the film thickness of the thermally conductive sheet and the cured product thereof can be more favorable.

It is preferable that the inorganic filler material (B) according to the present embodiment further includes, in addition to the secondary agglomerated particles, primary particles of scaly boron nitride that are different from the primary particles of the scaly boron nitride constituting the secondary agglomerated particles in terms of further improving thermal conductivity of the thermally conductive sheet and the cured product thereof. The average major diameter of these primary particles of scaly boron nitride is preferably greater than or equal to 0.01 μm and less than or equal to 20 μm and more preferably greater than or equal to 0.1 μm and less than or equal to 15 μm.

Accordingly, it is possible to realize the thermally conductive sheet and the cured product thereof having a more excellent balance of thermal conductivity and insulating properties.

### (Curing Agent (C))

It is preferable that the thermally conductive sheet according to the present embodiment further includes a curing agent (C) when an epoxy resin is used as the thermosetting resin (A).

One or more selected from a curing catalyst (C-1) and a phenol-based curing agent (C-2) can be used as the curing agent (C).

Examples of the curing catalyst (C-1) include an organometallic salt such as zinc naphthenate, cobalt naphthenate, tin octylate, cobalt octylate, bis acetylacetonate cobalt (II), or tris acetylacetonate cobalt (III); tertiary amines such as triethylamine, tributylamine, and 1,4-diazabicyclo[2.2.2]octane; imidazoles such as 2-phenyl-4-methylimidazole, 2-ethyl-4-methylimidazole, 2,4-diethylimidazole, 2-phenyl-4-methyl-5-hydroxyimidazole, and 2-phenyl-4,5-dihydroxymethylimidazole; organic phosphorus compounds such as triphenylphosphine, tri-p-tolylphosphine, tetraphenylphosphonium, tetraphenylborate, triphenylphosphine, and triphenylborane, 1,2-bis-(diphenylphosphino)ethane; phenol compounds such as phenol, bisphenol A, and nonylphenol; and organic acids such as acetic acid, benzoic acid, salicylic acid, and p-toluenesulfonic acid; or a mixture thereof. One of these examples including derivatives can be used alone as the curing catalyst (C-1), or two or more thereof including derivatives can be used together.

The content of the curing catalyst (C-1) in the thermally conductive sheet according to the present embodiment is not particularly limited and is preferably greater than or equal to 0.001 mass % and less than or equal to 1 mass % with respect to the thermally conductive sheet as 100 mass %.

Examples of the phenol-based curing agent (C-2) include a novolac-type phenol resin such as a phenol novolac resin, a cresol novolac resin, a naphthol novolac resin, an amino triazine novolac resin, a novolac resin, or a tris phenyl methane phenol novolac resin; a modified phenol resin such as a terpene-modified phenol resin or a dicyclopentadiene-modified phenol resin; an aralkyl resin such as a phenol aralkyl resin having a phenylene skeleton and/or a biphenylene skeleton or a naphthol aralkyl resin having a phenylene skeleton and/or a biphenylene skeleton; bisphenol compounds such as bisphenol A and bisphenol F; and a resol-type phenol resin. One of these may be used alone as the phenol-based curing agent (C-2), or two or more thereof may be used together.

Among the examples, the phenol-based curing agent (C-2) is preferably a novolac-type phenol resin or a resol-type phenol resin in terms of increasing the glass transition temperature and decreasing a linear expansion coefficient.

The content of the phenol-based curing agent (C-2) is not particularly limited and is preferably greater than or equal to 1 mass % and less than or equal to 30 mass % and more preferably greater than or equal to 5 mass % and less than or equal to 15 mass % with respect to the thermally conductive sheet as 100 mass %.

### (Coupling Agent (D))

The thermally conductive sheet according to the present embodiment may further include a coupling agent (D). The coupling agent (D) can improve wettability of an interface between the thermosetting resin (A) and the inorganic filler material (B).

Any of coupling agents normally used can be used as the coupling agent (D). Specifically, one or more coupling agents selected from an epoxysilane coupling agent, a cationic silane coupling agent, an aminosilane coupling agent, a titanate-based coupling agent, and a silicone oil coupling agent are preferably used.

The additive content of the coupling agent (D) is not particularly limited since being dependent on the specific surface area of the inorganic filler material (B) and is preferably greater than or equal to 0.1 parts by weight and less than or equal to 10 parts by weight and particularly preferably greater than or equal to 0.5 parts by weight and less than or equal to 7 parts by weight with respect to the inorganic filler material (B) as 100 parts by weight.

### (Phenoxy Resin (E))

The thermally conductive sheet according to the present embodiment may further include a phenoxy resin (E). Including the phenoxy resin (E) can further improve flex resistance of the thermally conductive sheet and the cured product thereof.

In addition, including the phenoxy resin (E) can decrease the modulus of elasticity of the thermally conductive sheet and the cured product thereof and can improve stress relaxation force of the thermally conductive sheet and the cured product thereof.

When the phenoxy resin (E) is included, fluidity due to viscosity increase is decreased, and occurrence of voids and the like can be suppressed. In addition, adhesion between the thermally conductive sheet and the thermal radiation member can be improved. Owing to the synergistic effects, insulating reliability of a semiconductor device can be further increased.

Examples of the phenoxy resin (E) include a phenoxy resin having a bisphenol skeleton, a phenoxy resin having a naphthalene skeleton, a phenoxy resin having an anthracene skeleton, and a phenoxy resin having a biphenyl skeleton. In addition, a phenoxy resin having a structure including one or more of these skeletons can also be used.

The content of the phenoxy resin (E) is, for example, greater than or equal to 3 mass % and less than or equal to 10 mass % with respect to the thermally conductive sheet as 100 mass %.

### (Other Components)

The thermally conductive sheet according to the present embodiment can include an antioxidant, a leveling agent, and the like to an extent without impairing the effect of the present invention.

The thermally conductive sheet according to the present embodiment can be prepared as follows.

First, each component above is added to a solvent to obtain a varnish-type resin composition. In the present embodiment, for example, a resin compound can be obtained by preparing a resin varnish through adding the thermosetting resin (A) and the like to a solvent, putting the inorganic filler material (B) into the resin varnish, and milling the inorganic filler material (B) and the resin varnish by using a three-roll mill or the like. Accordingly, the inorganic filler material (B) can be more uniformly dispersed in the thermosetting resin (A).

Examples of the solvent include, although not particularly limited, methyl ethyl ketone, methyl isobutyl ketone, propylene glycol monomethyl ether, and cyclohexanone.

Next, the resin composition for the thermally conductive sheet is aged. Accordingly, in the thermally conductive sheet obtained, the first pore diameter of the inorganic filler material (B) in the thermally conductive sheet can be increased, and the second pore diameter can be decreased. In consequence, the difference between the second pore diameter and the first pore diameter can be decreased.

Since affinity of the thermosetting resin (A) with respect to the inorganic filler material (B) is increased owing to aging, the thermosetting resin (A) sufficiently permeates into the inorganic filler material (B), and in consequence, voids in the particles of the inorganic filler material (B) can be held before and after manufacturing of the thermally conductive sheet. Thus, it is estimated that the first pore diameter can be increased.

In addition, owing to aging, affinity of the thermosetting resin (A) with respect to the inorganic filler material (B) is increased, and dispersibility of the inorganic filler material (B) in the thermosetting resin (A) is improved. Accordingly, since the filling ability of the inorganic filler material (B) is increased, it is estimated that the second pore diameter can be decreased.

Aging can be performed, for example, at 30 to 80° C. for 8 to 25 hours and preferably 12 to 24 hours under 0.1 to 1.0 MPa. Normally, as the aging temperature or the aging time is increased, the first pore diameter can be increased, and the second pore diameter can be decreased.

Next, the resin composition is shaped into a sheet to form the thermally conductive sheet. In the present embodiment, the thermally conductive sheet can be obtained by, for example, applying the varnish-type resin composition onto a base material and then heating and drying the varnish-type resin composition and the base material. Examples of the base material include a metal foil that constitutes a thermal radiation member, a lead frame, a peelable carrier material, and the like. Heating for drying the resin composition is performed, for example, at 80 to 150° C. for five minutes to one hour. The film thickness of the thermally conductive sheet is, for example, greater than or equal to 60 μm and less than or equal to 500 μm.

Next, it is preferable that the resin sheet is compressed by passing through between a two-roll mill to remove air bubbles in the resin sheet.

In the present embodiment, by including removing of air bubbles through applying compressive pressure with a roll as such, the inorganic filler material (B) is deformed due to the compressive pressure, and the difference between the second pore diameter and the first pore diameter of the inorganic filler material (B) in the thermally conductive sheet can be decreased.

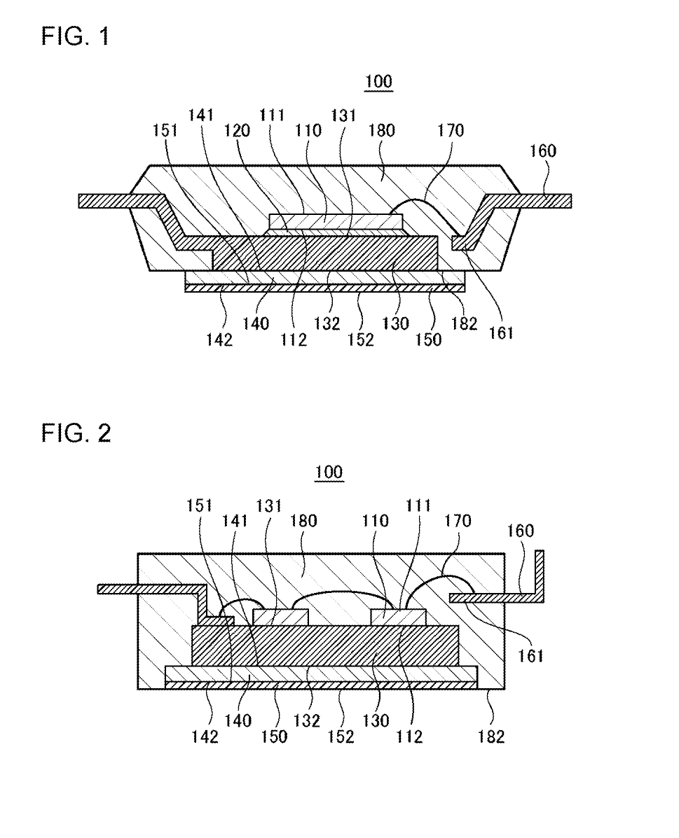

Next, a semiconductor device according to the present embodiment will be described. FIG. 1 is a sectional view of a semiconductor device 100 according to one embodiment of the present invention.

For simplification of description, a positional relationship (up and down relationship and the like) of each element constituting the semiconductor device 100 may be described below as in the relationship illustrated in each drawing. However, the positional relationship in the description is irrelevant to a positional relationship at the time of use or manufacturing of the semiconductor device 100.

The present embodiment will be described in the case where a metal plate is used as a heat sink. The semiconductor device 100 according to the present embodiment is provided with a heat sink 130, a semiconductor chip 110 disposed on a first face 131 side of the heat sink 130, a thermally conductive material 140 bonded to a second face 132 of the heat sink 130 opposite from the first face 131, and an encapsulating resin 180 encapsulating the semiconductor chip 110 and the heat sink 130.

Hereinafter, details of the semiconductor device 100 will be described.

The semiconductor device 100, for example, includes a conductive layer 120, a metal layer 150, a lead 160, and a wire (metal interconnect) 170 in addition to the above configuration.

An unillustrated electrode pattern is formed on an upper face 111 of the semiconductor chip 110, and an unillustrated conductive pattern is formed on a lower face 112 of the semiconductor chip 110. The lower face 112 of the semiconductor chip 110 is fixed to the first face 131 of the heat sink 130 through the conductive layer 120 such as silver paste. The electrode pattern on the upper face 111 of the semiconductor chip 110 is electrically connected to an electrode 161 of the lead 160 through the wire 170.

The heat sink 130 is configured of metal.

The encapsulating resin 180 encapsulates a part of the wire 170, the conductive layer 120, and the lead 160 inside the encapsulating resin 180 in addition to the semiconductor chip 110 and the heat sink 130. The other part of each lead 160 protrudes outside the encapsulating resin 180 from a side face of the encapsulating resin 180. In the present embodiment, for example, a lower face 182 of the encapsulating resin 180 and the second face 132 of the heat sink 130 are positioned in the same plane.

An upper face 141 of the thermally conductive material 140 is attached to the second face 132 of the heat sink 130 and the lower face 182 of the encapsulating resin 180. That is, the encapsulating resin 180 is in contact with the face (upper face 141) on the heat sink 130 side of the thermally conductive material 140 around the heat sink 130.

An upper face 151 of the metal layer 150 is fixed to a lower face 142 of the thermally conductive material 140. That is, one face (upper face 151) of the metal layer 150 is fixed to the face (lower face 142) of the thermally conductive material 140 opposite from the heat sink 130 side.

It is preferable that the outline of the upper face 151 of the metal layer 150 overlaps with the outline of the face (lower face 142) of the thermally conductive material 140 opposite from the heat sink 130 side in a plan view.

The entire face (lower face 152) of the metal layer 150 opposite from the one face (upper face 151) is exposed from the encapsulating resin 180. In the present embodiment, the upper face 141 of the thermally conductive material 140 is attached to the second face 132 of the heat sink 130 and the lower face 182 of the encapsulating resin 180 as described above. Thus, the thermally conductive material 140 is exposed outside the encapsulating resin 180 except for the upper face 141 thereof. The entire metal layer 150 is exposed outside the encapsulating resin 180.

The second face 132 and the first face 131 of the heat sink 130, for example, are formed flat.

The mounted floor area of the semiconductor device 100, although not particularly limited, can be greater than or equal to 10×10 mm and less than or equal to 100×100 mm as an example. The mounted floor area of the semiconductor device 100 is the area of the lower face 152 of the metal layer 150.

The number of semiconductor chips 110 mounted on one heat sink 130 is not particularly limited. The number may be one or more. For example, the number can be greater than or equal to three (six and the like). That is, for example, three or more semiconductor chips 110 may be disposed on the first face 131 side of one heat sink 130, and the encapsulating resin 180 may encapsulate all of these three or more semiconductor chips 110.

The semiconductor device 100 is, for example, a power semiconductor device. The semiconductor device 100 can be configured as 2-in-1 in which two semiconductor chips 110 are encapsulated in the encapsulating resin 180, 6-in-1 in which six semiconductor chips 110 are encapsulated in the encapsulating resin 180, or 7-in-1 in which seven semiconductor chips 110 are encapsulated in the encapsulating resin 180.

Next, an example of a method for manufacturing the semiconductor device 100 according to the present embodiment will be described.

First, the heat sink 130 and the semiconductor chip 110 are prepared, and the lower face 112 of the semiconductor chip 110 is fixed to the first face 131 of the heat sink 130 through the conductive layer 120 such as silver paste.

Next, a lead frame (not illustrated entirely) that includes the lead 160 is prepared, and the electrode pattern on the upper face 111 of the semiconductor chip 110 and the electrode 161 of the lead 160 are electrically connected through the wire 170.

Next, the semiconductor chip 110, the conductive layer 120, the heat sink 130, the wire 170, and a part of the lead 160 are encapsulated by the encapsulating resin 180.

Next, the thermally conductive material 140 is prepared, and the upper face 141 of the thermally conductive material 140 is attached to the second face 132 of the heat sink 130 and the lower face 182 of the encapsulating resin 180. Furthermore, one face (upper face 151) of the metal layer 150 is fixed to the face (lower face 142) of the thermally conductive material 140 opposite from the heat sink 130 side. The metal layer 150 may be fixed in advance to the lower face 142 of the thermally conductive material 140 before the thermally conductive material 140 is attached to the heat sink 130 and the encapsulating resin 180.

Next, each lead 160 is cut out of the frame body (not illustrated) of the lead frame. Accordingly, the semiconductor device 100 having the structure illustrated in FIG. 1 is obtained.

According to the embodiment thus far, the semiconductor device 100 is provided with the heat sink 130, the semiconductor chip 110 disposed on the first face 131 side of the heat sink 130, the insulating thermally conductive material 140 attached to the second face 132 of the heat sink 130 opposite from the first face 131, and the encapsulating resin 180 encapsulating the semiconductor chip 110 and the heat sink 130.

As described above, as the area of the package of the semiconductor device is larger, the electric field at a place in the faces of the thermally conductive material where the electric field is most concentrated is intensified even if degradation of insulating properties of the thermally conductive material is not actualized as a problem when the package of the semiconductor device is smaller than a certain size. Thus, it is considered that degradation of insulating properties due to slight varying of the film thickness of the thermally conductive material may also be actualized as a problem.

Regarding this point, the semiconductor device 100 according to the present embodiment can be expected to have sufficient durability by providing the thermally conductive material 140 having the above structure in the semiconductor device 100 even if the semiconductor device 100 is a large-size package such that the mounted floor area of the semiconductor device 100 is greater than or equal to 10×10 mm and less than or equal to 100×100 mm.

The semiconductor device 100 according to the present embodiment can be expected to have sufficient durability by providing the thermally conductive material 140 having the above structure in the semiconductor device 100 even if the semiconductor device 100 has a structure in which, for example, three or more semiconductor chips 110 are disposed on the first face 131 side of one heat sink 130, and the encapsulating resin 180 encapsulates all of these three or more semiconductor chips, that is, even if the semiconductor device 100 is a large-size package.

When the semiconductor device 100 is further provided with the metal layer 150 of which one face (upper face 151) is fixed to the face (lower face 142) of the thermally conductive material 140 opposite from the heat sink 130 side, heat can be suitably radiated by the metal layer 150. Thus, thermal radiation properties of the semiconductor device 100 are improved.

When the upper face 151 of the metal layer 150 is smaller than the lower face 142 of the thermally conductive material 140, the lower face 142 of the thermally conductive material 140 is exposed outside, and it is a concern that the thermally conductive material 140 may be cracked due to protruding objects such as foreign objects. Meanwhile, when the upper face 151 of the metal layer 150 is larger than the lower face 142 of the thermally conductive material 140, an end portion of the metal layer 150 appears to float in the air, and the metal layer 150 may be peeled when, for example, being handled during the manufacturing process.

Regarding this point, providing a structure in which the outline of the upper face 151 of the metal layer 150 overlaps with the outline of the lower face 142 of the thermally conductive material 140 in a plan view can suppress cracking of the thermally conductive material 140 and peeling of the metal layer 150.

The entire lower face 152 of the metal layer 150 is exposed from the encapsulating resin 180. Thus, heat can be radiated from the entire lower face 152 of the metal layer 150, and the semiconductor device 100 has high thermal radiation properties.

FIG. 2 is a sectional view of the semiconductor device 100 according to one embodiment of the present invention. The semiconductor device 100 is different from the semiconductor device 100 illustrated in FIG. 1 in the following aspect described but in other aspects is configured in the same manner as the semiconductor device 100 illustrated in FIG. 1.

In the present embodiment, the thermally conductive material 140 is encapsulated in the encapsulating resin 180. The metal layer 150 is also encapsulated in the encapsulating resin 180 except for the lower face 152 thereof. The lower face 152 of the metal layer 150 and the lower face 182 of the encapsulating resin 180 are positioned in the same plane.

FIG. 2 illustrates an example in which at least two or more semiconductor chips 110 are mounted on the first face 131 of the heat sink 130. The electrode patterns on the upper faces 111 of the semiconductor chips 110 are electrically connected to each other through the wire 170. For example, total six semiconductor chips 110 are mounted on the first face 131. That is, for example, each two semiconductor chips 110 are arranged into three arrays in the depth direction of FIG. 2.

A power module provided with a substrate and the semiconductor device 100 is obtained by mounting the semiconductor device 100 illustrated in FIG. 1 or FIG. 2 on a substrate (not illustrated).

The present invention is not limited to the embodiment above. Modifications, improvements, and the like are included in the present invention to an extent achieving the object of the present invention.

### Example

Hereinafter, the present invention will be described with examples and comparative examples, which do not limit the present invention. In the example, parts represent parts by weight unless otherwise specified. In addition, each thickness is represented as an average film thickness.

### (Preparing Secondary Agglomerated Particles Configured of Primary Particles of Scaly Boron Nitride)

A mixture (melamine borate: scaly boron nitride powder=10:1 (mass ratio)) obtained by mixing melamine borate (borate: melamine=2:1 (molar ratio)) and scaly boron nitride powder (average major diameter: 15 μm) is added to a 0.2 mass % polyacrylic acid ammonium aqueous solution and is mixed for two hours to prepare a slurry for spray drying granulation (polyacrylic acid ammonium aqueous solution:mixture=100:30 (mass ratio)). Next, the slurry is supplied to a spray granulator and is sprayed under conditions of a number of rotations of an atomizer of 15000 rpm, a temperature of 200° C., and an amount of supply of the slurry of 5 ml/min. Next, the obtained compound particles are baked in a nitrogen atmosphere at 2000° C. for 10 hours, and agglomerated boron nitride having an average particle diameter of 80 μm is obtained.

The average particle diameter of the agglomerated boron nitride is set as the median diameter (D₅₀) of a particle size distribution when a particle size distribution of particles is measured by a laser diffraction particle size measuring device (HORIBA, LA-500) on a volume basis.

### (Preparing Thermally Conductive Sheet)

The thermally conductive sheet is prepared in Examples 1 to 7 and in Comparative Examples 1 and 2 as follows.

First, according to the mixture illustrated in Table 1, a thermosetting resin and a curing agent are added to methyl ethyl ketone that is a solvent, and these are stirred to obtain a solution of a thermosetting resin composition. Next, an inorganic filler material is put into the solution and is premixed. Afterward, the solution is milled by a three-roll mill to obtain a resin composition for a thermally conductive sheet in which the inorganic filler material is uniformly dispersed. Next, the obtained resin composition for a thermally conductive sheet is aged at 60° C. under 0.6 MPa for 15 hours. Next, the resin composition for a thermally conductive sheet is applied onto a copper foil by using a doctor blade and is dried through heating at 100° C. for 30 minutes to prepare a resin sheet having a film thickness of 400 μm. Next, the resin sheet is compressed by passing through between a two-roll mill to remove air bubbles in the resin sheet, and a B-stage thermally conductive sheet having a film thickness of 200 μm is obtained.

Details of each component in Table 1 are as follows.

In Example 8, a thermally conductive sheet is prepared in the same manner as Example 1 except that the resin composition for a thermally conductive sheet is aged at 80° C. under 0.6 MPa for 20 hours.

In Example 9, a thermally conductive sheet is prepared in the same manner as Example 1 except that the resin composition for a thermally conductive sheet is aged at 40° C. under 0.6 MPa for 10 hours.

In Example 10, a thermally conductive sheet is prepared in the same manner as Example 1 except that the resin composition for a thermally conductive sheet is aged at 50° C. under 0.6 MPa for 15 hours.

In Example 11, a thermally conductive sheet is prepared in the same manner as Example 1 except that the resin composition for a thermally conductive sheet is aged at 30° C. under 0.6 MPa for 15 hours, and an epoxy resin 7 is used instead of an epoxy resin 1.

In Example 12, a thermally conductive sheet is prepared in the same manner as Example 1 except that the resin composition for a thermally conductive sheet is aged at 30° C. under 0.6 MPa for 20 hours, and an epoxy resin 8 is used instead of the epoxy resin 1.

In Comparative Example 3, a thermally conductive sheet is prepared in the same manner as Example 1 except that the resin composition for a thermally conductive sheet is not aged.

Details of each component in Table 1 are as follows.

### (Thermosetting Resin (A))

Epoxy Resin 1: epoxy resin having a dicyclopentadiene skeleton (Nippon Kayaku, XD-1000)

Epoxy Resin 2: epoxy resin having a biphenyl skeleton (Mitsubishi Chemical Corporation, YX-4000)

Epoxy Resin 3: epoxy resin having an adamantane skeleton (Idemitsu Kosan, E201)

Epoxy Resin 4: epoxy resin having a phenol aralkyl skeleton (Nippon Kayaku, NC-2000-L)

Epoxy Resin 5: epoxy resin having a biphenyl aralkyl skeleton (Nippon Kayaku, NC-3000)

Epoxy Resin 6: epoxy resin having a naphthalene aralkyl skeleton (Nippon Kayaku, NC-7000)

Epoxy Resin 7: bisphenol F epoxy resin (Dainippon Ink, 830S)

Epoxy Resin 8: bisphenol A epoxy resin (Mitsubishi Chemical Corporation, 828)

Cyanate Resin 1: phenol novolac cyanate resin (Lonza Japan, PT-30)

### (Curing Catalyst C-1)

Curing Catalyst 1:2-phenyl-4,5-dihydroxymethylimidazole (Shikoku Chemicals, 2PHZ-PW)

Curing Catalyst 2: triphenylphosphine (Hokko Chemical Industry)

### (Curing Agent C-2)

Phenol-based Curing Agent 1: tris phenyl methane phenol novolac resin (Meiwa Plastic Industries, MEH-7500) (Inorganic Filler Material (B))

Filler Material 1: agglomerated boron nitride prepared through preparation of secondary agglomerated particles configured by primary particles of the scaly boron nitride

Filler Material 2: agglomerated boron nitride having an average particle diameter of 80 μm, prepared through the same method as the preparation example of the secondary agglomerated particles except that the baking temperature is changed to 1500° C. and the baking time to 8 hours in the above preparation example

Filler Material 3: agglomerated boron nitride having an average particle diameter of 80 μm, prepared through the same method as the preparation example of the secondary agglomerated particles except that the baking temperature is changed to 2100° C. and the baking time to 15 hours in the above preparation example

### (Measuring Pore Diameter Distribution Curve)

First, the cured product of the thermally conductive sheet is obtained by heating the obtained thermally conductive sheet at 180° C. under 10 MPa for 40 minutes. Next, the cured product of the thermally conductive sheet is incinerated through heating at 700° C. under an atmospheric pressure for four hours. Next, a pore diameter distribution curve of the inorganic filler material (B) included in the incineration residue obtained is measured by a mercury penetration porosimeter (Shimadzu, Micromeritics pore distribution measuring device AutoPore 9520).

Specific details are as follows. The incineration residue is heated and dried at 100° C. for one hour under an atmospheric pressure and is evaporated to obtain a measurement sample (inorganic filler material (B)). Next, approximately 0.2 g of the obtained measurement sample is put into a standard 5 cc powder cell (stem capacity 0.4 cc) and is measured under an initial pressure of 7 kPa (approximately 1 psia, corresponds to a pore diameter of approximately 180 μm). For parameters of mercury, a default contact angle of mercury is set to 130 degrees in the device, and surface tension of mercury is set to 485 dynes/cm.

The first pore diameter and the second pore diameter are obtained from the pore diameter distribution curve obtained. The pore diameter at the first maximum value of the peak in the range where the pore diameter R is greater than or equal to 0.1 μm and less than or equal to 5.0 μm is set as the first pore diameter, and the pore diameter at the second maximum value in the range where the pore diameter R is greater than or equal to 10 μm and less than or equal to 30 μm is set as the second pore diameter. The difference between the second pore diameter and the first pore diameter is calculated by using the first pore diameter and the second pore diameter obtained.

In addition, the cumulative pore volume V1 in the range where the pore diameter R is greater than 5.0 μm and less than or equal to 180 μm and the cumulative pore volume V2 in the range where the pore diameter R is greater than or equal to 0.01 μm and less than or equal to 180 μm are obtained from the pore diameter distribution curve obtained.

### (Measuring Tg (Glass Transition Temperature))

The glass transition temperature of the cured product of the thermally conductive sheet is measured as follows. First, the cured product of the thermally conductive sheet is obtained by heating the obtained thermally conductive sheet at 180° C. under 10 MPa for 40 minutes. Next, the glass transition temperature (Tg) of the cured product obtained is measured through DMA (dynamic viscoelasticity measurement) under conditions of a rate of temperature increase of 5° C./min and a frequency of 1 Hz.

### (Evaluating Insulating Reliability)

Insulating reliability of the semiconductor package is evaluated as follows in each of Examples 1 to 12 and in each of Comparative Examples 1 to 3. First, the semiconductor package illustrated in FIG. 1 is prepared by using the cured product of the thermally conductive sheet. Next, insulation resistance in continuous humidity is evaluated under conditions of a temperature of 85° C., a humidity of 85%, and an alternating current voltage of 1.5 kV applied by using the semiconductor package. A resistance value less than or equal to 10⁶Ω is defined as a failure. Evaluation criteria are as follows.

AA: No failure occurs for 300 hours or more.

A: Failure occurs for 200 hours or more and less than 300 hours.

B: Failure occurs for 150 hours or more and less than 200 hours.

C: Failure occurs for 100 hours or more and less than 150 hours.

D: Failure occurs for less than 100 hours.

### (Heat Cycle Test)

The heat cycle of the semiconductor package is evaluated as follows in each of Examples 1 to 12 and in each of Comparative Examples 1 to 3. First, the semiconductor package illustrated in FIG. 1 is prepared by using the cured product of the thermally conductive sheet. Next, a heat cycle test is performed by using three of the semiconductor packages. The heat cycle test is performed for 3000 times with one cycle from −40° C. for 5 min to +125° C. for 5 min.

Next, an ultrasound imaging device (Hitachi Construction Machinery, FS300) is used to observe whether the semiconductor chip and the conductive layer are abnormal.

A: No abnormalities are found in the semiconductor chip and the conductive layer.

B: No problems are found in practical use although a part of the semiconductor chip and/or the conductive layer is cracked.

C: A part of the semiconductor chip and/or the conductive layer is cracked, and this may be a problem in practical use.

D: The semiconductor chip and the conductive layer are cracked and cannot be used.

TABLE 1

| | | | Unit | Example 1 | Example 2 | Example 3 | Example 4 | Example 5 | Example 6 | Example 7 | Example 8 |
|---|---|---|---|---|---|---|---|---|---|---|---|
| Resin | Thermosetting | Epoxy | g | 18.9 | — | — | — | — | — | — | 18.9 |
| composition | Resin | Resin 1 | | | | | | | | | |
| | | Epoxy | g | — | 9.0 | 8.6 | — | — | — | 12.9 | — |
| | | Resin 2 | | | | | | | | | |
| | | Epoxy | g | — | — | 8.9 | — | — | — | — | — |
| | | Resin 3 | | | | | | | | | |
| | | Epoxy | g | — | — | — | 18.6 | — | — | — | — |
| | | Resin 4 | | | | | | | | | |
| | | Epoxy | g | — | — | — | — | 19.4 | — | — | — |
| | | Resin 5 | | | | | | | | | |
| | | Epoxy | g | — | — | — | — | — | 18.4 | — | — |
| | | Resin 6 | | | | | | | | | |
| | | Epoxy | g | — | — | — | — | — | — | — | — |
| | | Resin 7 | | | | | | | | | |
| | | Epoxy | g | — | — | — | — | — | — | — | — |
| | | Resin 8 | | | | | | | | | |
| | | Cyanate | g | — | — | — | — | — | — | 12.9 | — |
| | | Resin 1 | | | | | | | | | |
| | Curing Agent | Phenol- | g | 7.3 | 17.2 | 8.8 | 7.6 | 6.8 | 7.8 | — | 7.3 |
| | | based | | | | | | | | | |
| | | Curing | | | | | | | | | |
| | | Agent 1 | | | | | | | | | |
| | | Curing | g | 0.1 | 0.1 | 0.1 | 0.1 | 0.1 | 0.1 | — | 0.1 |
| | | Catalyst 1 | | | | | | | | | |
| | | Curing | g | — | — | — | — | — | — | 0.5 | — |
| | | Catalyst 2 | | | | | | | | | |
| | Inorganic | Filler | g | 73.8 | 73.8 | 73.8 | 73.8 | 73.8 | 73.8 | 73.8 | 73.8 |
| | Filler Material | Material 1 | | | | | | | | | |
| | | Filler | g | — | — | — | — | — | — | — | — |
| | | Material 2 | | | | | | | | | |
| | | Filler | g | — | — | — | — | — | — | — | — |
| | | Material 3 | | | | | | | | | |

| | | | | | | | | | |
|---|---|---|---|---|---|---|---|---|---|
| First Pore Diameter | μm | 0.72 | 0.72 | 0.72 | 0.72 | 0.72 | 0.72 | 0.72 | 0.80 |
| Second Pore Diameter | μm | 18.1 | 18.1 | 18.1 | 18.1 | 18.1 | 18.1 | 18.1 | 13.0 |
| Difference between Second Pore | μm | 17.4 | 17.4 | 17.4 | 17.4 | 17.4 | 17.4 | 17.4 | 12.2 |
| Diameter and First Pore Diameter | | | | | | | | | |
| Cumulative Pore Volume V1 | mL/g | 0.565 | 0.565 | 0.565 | 0.565 | 0.565 | 0.565 | 0.565 | 0.565 |
| Cumulative Pore Volume V2 | mL/g | 0.962 | 0.962 | 0.962 | 0.962 | 0.962 | 0.962 | 0.962 | 0.962 |
| Glass Transition Temperature (Tg) | ° C. | 197 | 185 | 221 | 169 | 167 | 190 | 288 | 192 |
| Insulating Reliability Evaluation | — | AA | A | A | B | B | A | A | A |
| Heat Cycle Test | — | A | A | A | A | A | A | A | A |

| | | | | | | | | Comparative | Comparative | Comparative |
|---|---|---|---|---|---|---|---|---|---|---|
| | | | Unit | Example 9 | Example 10 | Example 11 | Example 12 | Example 1 | Example 2 | Example 3 |
| Resin | Thermosetting | Epoxy | g | 18.9 | 18.9 | — | — | 18.9 | 18.9 | 18.9 |
| composition | Resin | Resin 1 | | | | | | | | |
| | | Epoxy | g | — | — | — | — | — | — | — |
| | | Resin 2 | | | | | | | | |
| | | Epoxy | g | — | — | — | — | — | — | — |
| | | Resin 3 | | | | | | | | |
| | | Epoxy | g | — | — | — | — | — | — | — |
| | | Resin 4 | | | | | | | | |
| | | Epoxy | g | — | — | — | — | — | — | — |
| | | Resin 5 | | | | | | | | |
| | | Epoxy | g | — | — | — | — | — | — | — |
| | | Resin 6 | | | | | | | | |
| | | Epoxy | g | — | — | 18.9 | — | — | — | — |
| | | Resin 7 | | | | | | | | |
| | | Epoxy | g | — | — | — | 18.9 | — | — | — |
| | | Resin 8 | | | | | | | | |
| | | Cyanate | g | — | — | — | — | — | — | — |
| | | Resin 1 | | | | | | | | |
| | Curing Agent | Phenol- | g | 7.3 | 7.3 | 7.3 | 7.3 | 7.3 | 7.3 | 7.3 |
| | | based | | | | | | | | |
| | | Curing | | | | | | | | |
| | | Agent 1 | | | | | | | | |
| | | Curing | g | 0.1 | 0.1 | 0.1 | 0.1 | 0.1 | 0.1 | 0.1 |
| | | Catalyst 1 | | | | | | | | |
| | | Curing | g | — | — | — | — | — | — | — |
| | | Catalyst 2 | | | | | | | | |
| | Inorganic | Filler | g | 73.8 | 73.8 | 73.8 | 73.8 | — | — | 73.8 |
| | Filler Material | Material 1 | | | | | | | | |
| | | Filler | g | — | — | — | — | 73.8 | — | — |
| | | Material 2 | | | | | | | | |
| | | Filler | g | — | — | — | — | — | 73.8 | — |
| | | Material 3 | | | | | | | | |

| | | | | | | | | |
|---|---|---|---|---|---|---|---|---|
| First Pore Diameter | μm | 0.30 | 0.60 | 0.21 | 0.23 | 0.02 | 1.2 | 0.40 |
| Second Pore Diameter | μm | 19.0 | 18.5 | 19.0 | 19.5 | 28.0 | 10.5 | 27.0 |
| Difference between Second Pore | μm | 18.7 | 17.9 | 18.8 | 19.3 | 28.0 | 9.3 | 26.6 |
| Diameter and First Pore Diameter | | | | | | | | |
| Cumulative Pore Volume V1 | mL/g | 0.742 | 0.717 | 0.803 | 0.854 | 1.700 | 1.050 | 1.800 |
| Cumulative Pore Volume V2 | mL/g | 1.354 | 1.394 | 1.479 | 1.587 | 1.800 | 1.900 | 1.900 |
| Glass Transition Temperature (Tg) | ° C. | 194 | 191 | 166 | 170 | 194 | 193 | 195 |
| Insulating Reliability Evaluation | — | B | A | B | B | D | D | C |
| Heat Cycle Test | — | A | A | B | B | D | D | C |

The semiconductor packages of Examples 1 to 12 in which the thermally conductive sheet having the difference of the second pore diameter and the first pore diameter within the above range described in the present invention is used have excellent insulating reliability and an excellent heat cycle.

Meanwhile, the semiconductor packages of Comparative Examples 1 to 3 in which the thermally conductive sheet having the difference of the second pore diameter and the first pore diameter outside the above range described in the present invention is used have inferior insulating reliability and an inferior heat cycle.

Therefore, it is understood that a highly durable semiconductor device is obtained by using the thermally conductive sheet of the present invention.

It is apparent that the present invention is not limited to the above embodiment, and may be modified and changed without departing from the scope and spirit of the invention.

What is claimed is:

1. A thermally conductive sheet that includes a thermosetting resin and an inorganic filler material which is dispersed in the thermosetting resin,
wherein when a pore diameter distribution is measured through mercury intrusion technique for the inorganic filler material that is included in an incineration residue after a cured product of the thermally conductive sheet is heated at 700° C. for four hours and is incinerated,
a pore diameter distribution curve of the inorganic filler material, that is measured through the mercury intrusion technique and is plotted with a pore diameter R as a horizontal axis and a logarithmic derivative of a pore volume (dV/d log R) as a vertical axis, has
a first maximum value in the range where the pore diameter R is greater than or equal to 0.1 μm and less than or equal to 5.0 μm, and
a second maximum value in the range where the pore diameter R is greater than or equal to 10 μm and less than or equal to 30 μm, and
the difference between a second pore diameter at the second maximum value and a first pore diameter at the first maximum value is greater than or equal to 9.9 μm and less than or equal to 25 μm.

2. The thermally conductive sheet according to claim 1,
wherein a cumulative pore volume V1 in the range where the pore diameter R is greater than 5.0 μm and less than or equal to 180 μm is greater than or equal to 0.4 mL/g and less than or equal to 1.0 mL/g, and
a cumulative pore volume V2 in the range where the pore diameter R is greater than or equal to 0.01 μm and less than or equal to 180 μm is greater than or equal to 0.8 mL/g and less than or equal to 1.7 mL/g.

3. The thermally conductive sheet according to claim 1,
wherein the inorganic filler material is secondary agglomerated particles that are configured of primary particles of scaly boron nitride.

4. The thermally conductive sheet according to claim 3,
wherein the average major diameter of the primary particles constituting the secondary agglomerated particles is greater than or equal to 0.01 μm and less than or equal to 20 μm.

5. The thermally conductive sheet according to claim 1,
wherein the average particle diameter of the inorganic filler material is greater than or equal to 5 μm and less than or equal to 180 μm.

6. The thermally conductive sheet according to claim 1,
wherein the content of the inorganic filler material is greater than or equal to 50 mass % and less than or equal to 95 mass % with respect to the thermally conductive sheet as 100 mass %.

7. The thermally conductive sheet according to claim 1,
wherein the thermosetting resin is one or two or more selected from an epoxy resin having a dicyclopentadiene skeleton, an epoxy resin having a biphenyl skeleton, an epoxy resin having an adamantane skeleton, an epoxy resin having a phenol aralkyl skeleton, an epoxy resin having a biphenyl aralkyl skeleton, an epoxy resin having a naphthalene aralkyl skeleton, and a cyanate resin.

8. The thermally conductive sheet according to claim 1,
wherein a glass transition temperature of a cured product of the thermally conductive sheet is greater than or equal to 175° C., which is measured through dynamic viscoelasticity measurement under conditions of a rate of temperature increase of 5° C./min and a frequency of 1 Hz.

9. A cured product of a thermally conductive sheet that is obtained by curing the thermally conductive sheet according to claim 1.

10. A semiconductor device comprising:
a metal plate;
a semiconductor chip that is disposed on a first face side of the metal plate;
a thermally conductive material that is bonded to a second face of the metal plate opposite from the first face; and
an encapsulating resin that encapsulates the semiconductor chip and the metal plate,
wherein the thermally conductive material is formed by the thermally conductive sheet according to claim 1.
